(19) United States
(12) Patent Application Publication
(10) Pub. No.: US 2021/0305070 A1
(43) Pub. Date: Sep. 30, 2021

(54) OBJECT PROCESSING APPARATUS

(71) Applicant: ULVAC, INC., Chigasaki-shi (JP)

(72) Inventors: Tsuyoshi KAGAMI, Chigasaki-shi (JP); Hidenori FUKUMOTO, Chigasaki-shi (JP)

(21) Appl. No.: 16/495,650

(22) PCT Filed: Oct. 15, 2018
(86) PCT No.: PCT/JP2018/038294

§ 371 Date: Sep. 19, 2019

(30) Foreign Application Priority Data
Oct. 17, 2017 (JP) 2017-201074

(51) Int. Cl. H01L 21/67; H01J 37/32

(52) U.S. Cl. CPC H01L 21/67069; H01J 37/3244; H01J 2237/3343; H01J 37/32568; H01J 37/32816

(57) ABSTRACT

An object processing apparatus comprising a chamber that has an internal space able to be depressurized and is configured such that a target object is subjected to a plasma treatment in the internal space; a first electrode that is disposed in the chamber and on which the target object is to be mounted; a first power supply that applies a bias voltage of negative potential to the first electrode; a gas introduction device that introduces a processing gas into an inside of the chamber; and a pumping device that depressurizes the inside of the chamber. A cover is provided between the first electrode and the target object so as to cover the first electrode. A spacer is located between the first electrode and the cover, and is disposed so as to occupy a localized region.

### CROSS REFERENCE TO RELATED APPLICATIONS

This application is the U.S. National Phase Application under 35 U.S.C. § 371 of International Patent Application No. PCT/JP2018/038294 filed Oct. 15, 2018, which designated the United States and was published in a language other than English, which claims the benefit of Japanese Patent Application No. 2017-201074 filed on Oct. 17, 2017, both of which are incorporated by reference herein.

### FIELD

The present invention relates to an object processing apparatus which is capable of uniformly etching a substrate or a substrate on which a thin film or the like is formed (hereinafter, referred to as “target object”, more particularly, relates to an object processing apparatus which is used in the case of forming a film on a semiconductor substrate made of silicon, quartz, a glass, or the like by a sputtering method or a chemical vapor deposition method, in the case of etching the substrate including the formed film, or in the case of etching a natural oxide film or an undesired substance which is generated on a substrate surface.

### BACKGROUND

In etching treatment, ions generated from plasma are accelerated due to a negative self-bias voltage and collide against a target object. In such etching treatment, in accordance with an increase in the size of a substrate that is the target object, it becomes difficult to maintain uniformity in etching on a surface of the substrate.

In contrast, a plasma processing apparatus and a plasma treatment method are disclosed which separate an electrode and include a plurality of high-frequency power supplies in order to carry out etching by uniform plasma treatment on a surface of a substrate (for example, Patent Document 1). In addition, a plasma treatment method and a plasma processing apparatus are suggested which include a plurality of high-frequency power supplies having different frequency and thereby carry out excellent plasma treatment on a surface of a substrate (for example, Patent Document 2).

However, in the plasma processing apparatus disclosed in Patent Document 1 or Patent Document 2, the electrode configuration thereof is complicated, maintenance therefor is deteriorated, and it is necessary to arrange a plurality of power supplies. Accordingly, there are problems in that the footprint of the apparatus increases and the cost required to operate the apparatus increases.

Furthermore, in order to prevent a film from being adhered to the inside of a chamber of a plasma processing apparatus, a countermeasure of providing a cover formed of quartz, alumina, or the like is employed (for example, refer to Patent Document 3). In the case where the above-described cover is provided on an electrode on which a target object is to be mounted, in consideration of maintenance therefor, the cover is a separated member different from the electrode. Therefore, due to combination of the cover and the electrode or due to shapes of two surfaces at which the cover and the electrode are in contact with each other, a gap occurs between the two plane surfaces, and a difference in a space height of the gap may occur. The surface (upper surface) of a target object which is to be subjected to a plasma treatment is affected by the space height.

In etching treatment, ions generated from plasma are accelerated due to a negative self-bias voltage and collide against a target object. For this reason, in the etching treatment, the difference in the above-mentioned space height becomes a factor that causes a plasma treatment with respect to the surface (upper surface) of the target object which is to be subjected to the plasma treatment to be non-uniform. This is because the factor affects an introduction amount of a gas used for a plasma treatment or a process condition such as a pressure, causes an optimal range therefor to be narrow or an optimal range to be lost.

Consequently, development of a plasma treatment method and a plasma processing apparatus have been expected which provides excellent maintenance, can inexpensively realize the same effect as those of Patent Document 1 or Patent Document 2, and it is also possible to solve a problem in that the surface of a target object which is to be subjected to a plasma treatment is affected by a difference in the above-mentioned space height.

### PRIOR ART DOCUMENTS

### Patent Documents

(Patent Document 1) Japanese Unexamined Patent Application, First Publication No. 2011-228436
(Patent Document 2) Japanese Unexamined Patent Application, First Publication No. 2008-244429
(Patent Document 3) Japanese Unexamined Patent Application, First Publication No. 2006-5147

### SUMMARY

### Problems to be Solved by the Invention

The invention was conceived in view of the above-described conventional circumstances and has an object thereof to provide a plasma processing apparatus that provides excellent maintenance and can uniformly etch a target object.

### Means for Solving the Problems

An object processing apparatus according to one aspect of the invention includes a chamber that has an internal space able to be depressurized and is configured such that a target object (substrate) is subjected to a plasma treatment in the internal space; a first electrode (support base) that is disposed in the chamber and on which the target object is to be mounted; a first power supply that applies a bias voltage of negative potential to the first electrode; a gas introduction device that introduces a processing gas into an inside of the chamber; and a pumping device that depressurizes the inside of the chamber. A cover (electrode cover) is provided between the first electrode and the target object so as to cover the first electrode. A spacer is located between the first electrode and the cover, and is disposed so as to occupy a localized region.

In the object processing apparatus according to one aspect of the invention, the spacer may be formed of a thin structure (extremely-thin member).

In the object processing apparatus according to one aspect of the invention, a thickness (mm) of the spacer may be 0.1 to 0.5.

In the object processing apparatus according to one aspect of the invention, a thickness (mm) of the spacer may be 0.5 to 2.5 times the sum of tolerances of the first electrode and the cover on a surface on which the first electrode and the cover face each other.

In the object processing apparatus according to one aspect of the invention, the spacer is formed of a hollow structure (frame-shaped member).

In the object processing apparatus according to one aspect of the invention, a thickness (mm) of the spacer may be 0.1 to 0.5.

In the object processing apparatus according to one aspect of the invention, a thickness (mm) of the spacer may be 0.5 to 2.5 times the sum of tolerances of the first electrode and the cover on a surface on which the first electrode and the cover face each other.

The object processing apparatus according to one aspect of the invention may further include a conductive plate provided between the first electrode and the cover, and the spacer may be disposed between the cover and the plate.

### Effects of the Invention

In the object processing apparatus according to one aspect of the invention, the cover is disposed between the first electrode and the target object (substrate), and the spacer is located between the first electrode and the cover and is disposed at a localized region. Consequently, a configuration is obtained which can locally control a separated distance between the first electrode and the cover.

Between the two surfaces at which the first electrode and the cover face each other, a gap occurs due to geometric tolerance of each surface when the two surfaces are combined. In contrast, according to the object processing apparatus having the aforementioned configuration, due to modification of a position to which the spacer is inserted, a shape of the spacer, a size thereof (particularly, height), or the like, a state is obtained where the spacer is inserted to a gap that occurs between the two surfaces at which the first electrode and the cover face each other. Consequently, on the plane surface of the target object which is subjected to a plasma treatment, a problem is solved in that a difference in height of the space (gap) between the first electrode and the cover occurs, and it is possible to adjust impedance of an optional position. Thus, according to the object processing apparatus according to one aspect of the invention, a plasma treatment can be carried out on a plane surface of the substrate by a uniform negative electrical potential bias. In addition, the object processing apparatus according to one aspect of the invention, the above-mentioned effects can be naturally obtained only by replacing a spacer or only by changing an arrangement of the spacer. Therefore, it contributes to provision of an object processing apparatus which also provides excellent maintenance.

Moreover, in the configuration of the object processing apparatus according to one aspect of the invention in which a conductive plate is further provided between the first electrode and the cover and in which the spacer is disposed between the cover and the plate, the above-described actions and effects are similarly obtained.

As the spacer, a thin structure or a hollow structure is preferred. Consequently, due to provision of the spacer, local fine adjustment of a space height on a plane surface can be realized in accordance with the surface profiles of the portions (first electrode, cover, plate) with which the upper surface and the lower surface of the spacer come into contact. The thickness of the foregoing spacer is 0.1 mm to 0.5 mm and is preferably 0.5 to 2.5 times the sum of tolerances of the first electrode and the cover on a surface on which the first electrode and the cover face each other. Accordingly, it is possible to carry out plasma treatment with a uniform bias on a surface of the target object.

### BRIEF DESCRIPTION OF THE DRAWINGS

FIG. 1 is a schematic cross-sectional view showing an object processing apparatus according to an embodiment of the invention.

FIG. 2 is a schematic cross-sectional view showing an example of a mounting unit for the target object provided in the processing apparatus shown in FIG. 1.

FIG. 3 is a schematic cross-sectional view showing another example of a mounting unit for the target object provided in the processing apparatus shown in FIG. 1.

FIG. 4 is a schematic plan view showing an example of a spacer.

FIG. 5 is a schematic plan view showing another example of a spacer.

FIG. 6 is a schematic plan view showing another example of a spacer.

FIG. 7 is a schematic plan view showing another example of a spacer.

FIG. 8 is a schematic plan view showing another example of a spacer.

FIG. 9 is a schematic plan view showing another example of a spacer.

FIG. 10 is a schematic plan view showing another example of a spacer.

FIG. 11 is a schematic plan view showing another example of a spacer.

FIG. 12A is a graph showing a normalized etching rate.

FIG. 12B is a graph showing a normalized etching rate.

FIG. 12C is a map showing an etching rate.

FIG. 13A is a map showing an etching rate.

FIG. 13B is a map showing an etching rate.

FIG. 13C is a map showing an etching rate.

FIG. 13D is a map showing an etching rate.

FIG. 13E is a schematic plan view showing a state where the spacer overlaps the substrate.

FIG. 14A is a map showing an etching rate.

FIG. 14B is a map showing an etching rate.

FIG. 14C is a map showing an etching rate.

FIG. 15 is a schematic cross-sectional view showing, when two surfaces facing each other are combined, a gap that occurs between two surfaces due to geometric tolerance.

FIG. 16A is a plan view showing a state where a frame-shaped spacer is mounted on the plate.

FIG. 16B is an enlarged plan view showing a region near the spacer shown in FIG. 16A.

FIG. 17A is a map showing an etching rate and corresponding to FIGS. 16A and 16B.

FIG. 17B is a map showing an etching rate and corresponding to FIGS. 16A and 16B.

FIG. 17C is a map showing an etching rate and corresponding to FIGS. 16A and 16B.

FIG. 17D is a map showing an etching rate and corresponding to FIGS. 16A and 16B.

FIG. 17E is a map showing an etching rate and corresponding to FIGS. 16A and 16B.

FIG. 18A is a plan view showing a state where a blanket-shaped spacer is mounted on the plate.

FIG. 18B is an enlarged plan view showing a region near the spacer shown in FIG. 18A.

FIG. 19A is a map showing an etching rate and corresponding to FIGS. 18A and 18B.

FIG. 19B is a map showing an etching rate and corresponding to FIGS. 18A and 18B.

FIG. 19C is a map showing an etching rate and corresponding to FIGS. 18A and 18B.

FIG. 19D is a map showing an etching rate and corresponding to FIGS. 18A and 18B.

FIG. 19E is a map showing an etching rate and corresponding to FIGS. 18A and 18B.

FIG. 20 is a list showing the evaluation result of an experimental example 1.

FIG. 21 is a list showing the evaluation result of an experimental example 2.

FIG. 22 is a list showing the evaluation result of an experimental example 3.

FIG. 23 is a list showing the evaluation result of an experimental example 4.

### DETAILED DESCRIPTION

Hereinafter, a schematic cross-sectional view showing an object processing apparatus will be described with reference to drawings.

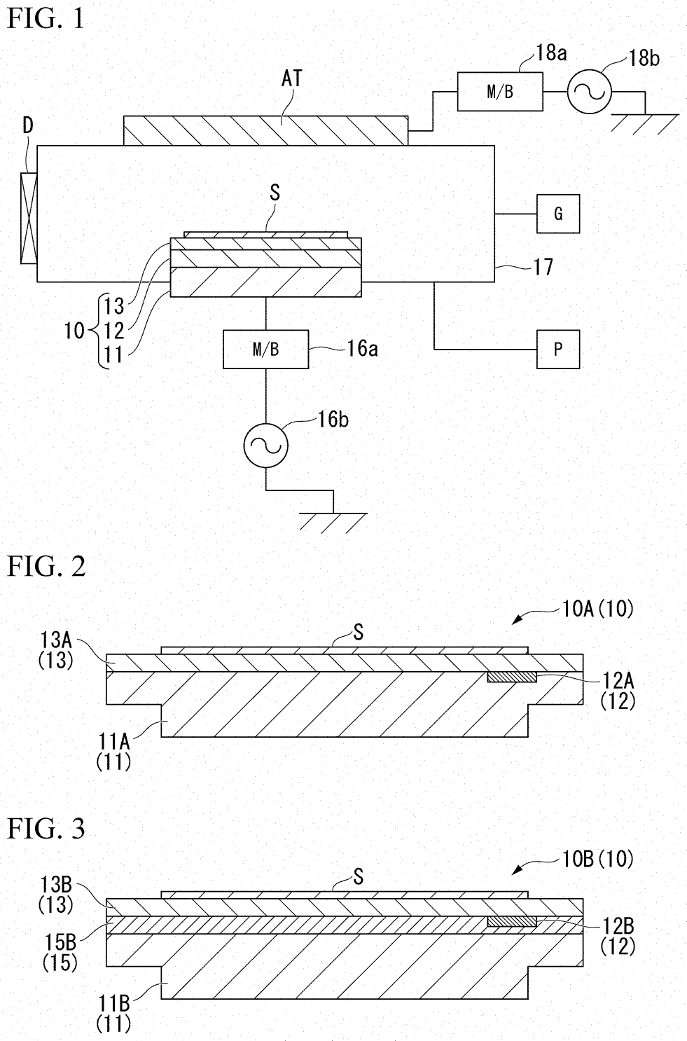

FIG. 1 is a schematic cross-sectional view showing an object processing apparatus according to an embodiment of the invention.

The object processing apparatus which is shown in shown in FIG. 1 includes a chamber 17 that has an internal space able to be depressurized and is configured such that a target object (substrate S) is subjected to plasma treatment in the internal space. The chamber 17 is connected to a multi-chamber apparatus (not shown in the figure) with an isolation valve D interposed therebetween.

The chamber 17 includes: a gas introduction device G that introduces a processing gas into the inside of the chamber; and a pumping device P that reduces a pressure inside the chamber.

A first electrode (support base) 11 on which the target object is to be mounted is disposed at the lower side inside the chamber 17. A first matching box (M/B) 16a and the first electrode 11 are disposed outside the chamber 17. The first power supply 16b is electrically connected to the first electrode 11 via the first matching box (M/B) 16a and applies a bias voltage of negative potential to the first electrode 11.

A plate (adjustment plate) 12 and a cover (electrode cover) 13 are stacked in this order on the first electrode 11 inside the chamber 17. The first electrode 11, the plate 12, and the cover 13 constitute a mounting unit 10 for the target object. The substrate S serving as the target object is to be mounted on the cover (electrode cover) 13. For example, operation of opening and closing the isolation valve D is carried out, and entering and taking out of the substrate S is carried out between the multi-chamber apparatus and (not shown in the figure) and the chamber 17 by use of a robot hand (not shown in the figure).

A spiral shaped second electrode (antenna coil) AT is arranged on an upper lid of the chamber 17 at the position opposed to the first electrode 11 outside the chamber 17. A second power supply 18b that applies a high-frequency voltage to the second electrode AT via a second matching box (M/B) 18a is electrically connected to the second electrode AT. The second power supply 18b is a high-frequency power supply (1 MHz to 100 MHz) for generating plasma by the processing gas to which a high-frequency voltage is applied.

FIG. 2 is an enlarged schematic cross-sectional view showing an example of a mounting unit for the target object provided in the processing apparatus shown in FIG. 1. In the configuration example of the mounting unit 10A (10) shown in FIG. 2, the cover 13A (13) is disposed so as to be stacked on the first electrode 11A (11). Furthermore, a spacer 12A (12) is provided between the first electrode 11A and the cover 13A.

The cover 13A is formed of an insulating member (for example, quartz or the like). The cover 13A has a function of preventing a film from being adhered to the first electrode 11A.

In the configuration shown in FIG. 2, due to combination of the first electrode 11A and the cover 13A, a slight space (the height thereof is referred to as “space height” in the invention) occurs between the two surfaces at which the first electrode 11A and the cover 13A face each other. Due to the presence of the space SP, a difference in attraction of ions from plasma by a bias effect occurs on the plane surface of the first electrode 11A. This interferes with uniform processing on the plane surface of the target object (the substrate S). In the embodiment of the invention, as a result of inserting and disposing the spacer 12A between the first electrode 11A and the cover 13A, adjustment of the space SP is carried out, a plasma treatment contributing to a uniform profile on the substrate S is achieved.

FIG. 3 is an enlarged schematic cross-sectional view showing another example of a mounting unit for the target object provided in the processing apparatus shown in FIG. 1. In the configuration example of a mounting unit 10B (10) shown in FIG. 3, the plate 15B (15) and a cover 13B (13) are disposed so as to be stacked in this order on a first electrode 11B (11). Furthermore, a spacer 12B (12) that is the feature of the invention is provided between the plate 15B and the cover 13B.

The configuration shown in FIG. 3 also obtains the same actions and effects as the above-mentioned configuration shown in FIG. 2. That is, in the configuration shown in FIG. 3, due to combination of the plate 15B and the cover 13B, a slight space (the height thereof is referred to as “space height” in the invention) occurs between the two surfaces at which the plate 15B and the cover 13B face each other. Due to the presence of the space SP, a difference in attraction of ions from plasma by a bias effect occurs on the plane surface of the first electrode 11B. This interferes with uniform processing on the plane surface of the target object (the substrate S). In the embodiment of the invention, as a result of inserting and disposing the spacer 12A between the plate 15B and the cover 13B, adjustment of the space SP is carried out, a plasma treatment contributing to a uniform profile on the substrate S is achieved.

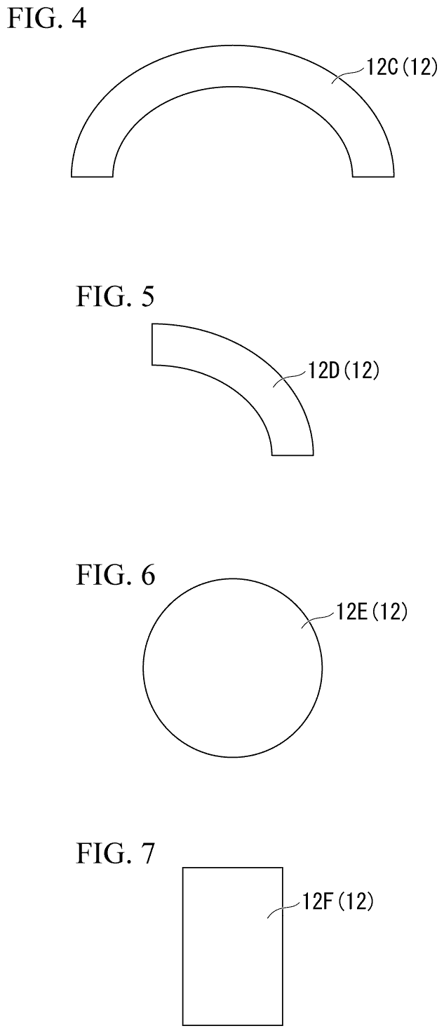

FIGS. 4 to 11 are schematic plan views showing various spacers used in the mounting unit for the target object shown in FIG. 2 or FIG. 3. In the following explanation, a ring shape is also referred to as “frame shape (simple frame shape)” or a hollow structure (frame shape). A circular shape and a rectangular shape are also referred to as “blanket shape (sheet shape)” or “thin structure (extremely-thin shape)”.

A spacer 12C shown in FIG. 4 has a shape obtained by cutting off a semicircular portion that is half of the ring shape having a predetermined width in the circumferential direction.

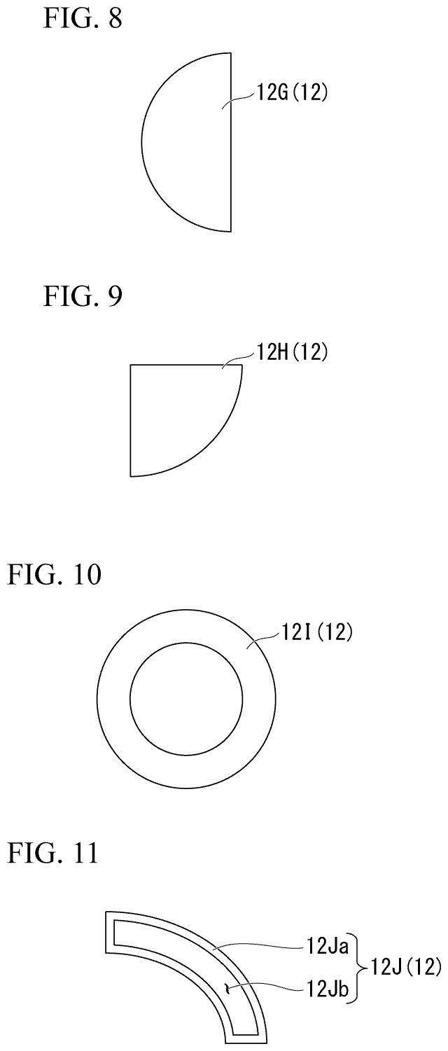

A spacer 12D shown in FIG. 5 has a shape obtained by cutting off a circular portion that is quarter of the ring shape having a predetermined width. A spacer 12E shown in FIG. 6 has a circular shape. A spacer 12F shown in FIG. 7 has a rectangular shape. A spacer 12G shown in FIG. 8 has a shape obtained by cutting off a semicircular portion of a circular shape. A spacer 12H shown in FIG. 9 has a shape obtained by cutting off a circular portion that is quarter of a circular shape.

All of the spacers shown in FIGS. 4 to 9 are each a sheet and are each “frame shape (sheet shape)” that does not have a region on which the center portion of the spacer is cut.

A spacer 12I shown in FIG. 10 has a ring shape having a predetermined width. A spacer 12J shown in FIG. 11 is a frame 12Ja having an outline forming a circular portion that is quarter of a ring shape having a predetermined width. The spacer 12J has a space 12Jb formed inside the frame 12Ja.

All of the spacers shown in FIGS. 10 and 11 are each a sheet and are each “frame shape (simple frame shape)” that has a space on which the center of the frame having a predetermined external outline is cut.

A plasma etching treatment was carried out on the substrate S serving as the target object by the object processing apparatus according to the embodiment and uniformity of an etching rate profile on the surface of the substrate S due to the spacer was evaluated.

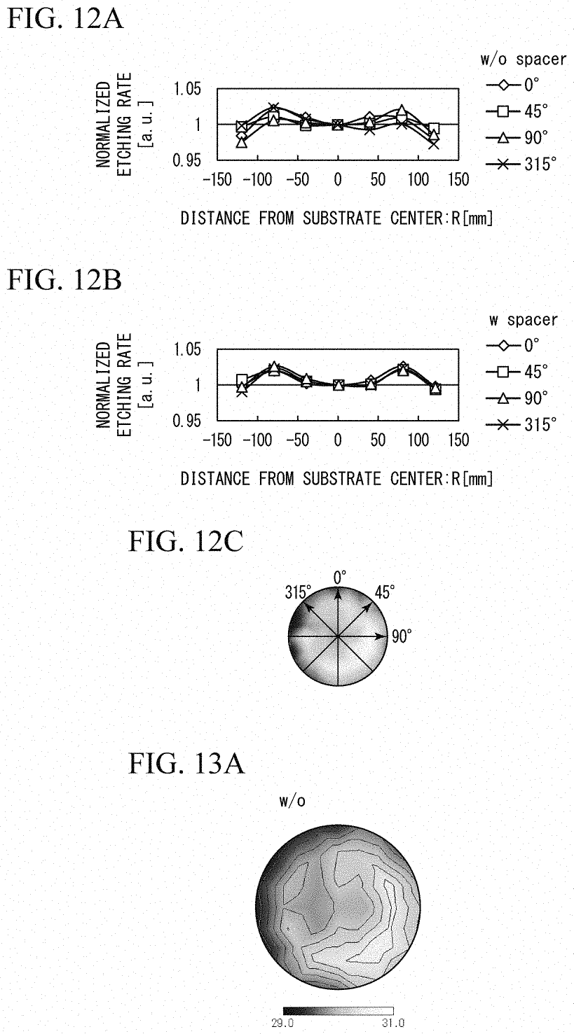

FIGS. 12A and 12B are each a graph showing a normalized etching rate. FIGS. 12A and 12B show the effects obtained by insertion of the spacer into the object processing apparatus as described above. FIG. 12A shows the case where the spacer is absent (w/o spacer). FIG. 12B shows the case where the spacer is present (w/o spacer). FIG. 12C is a map showing an etching rate corresponding to FIG. 12B.

In each of FIGS. 12A and 12B, the X-axis is “distance from center of substrate (target object) R (mm)”, and the Y-axis is “normalized etching rate (a.u.)”. The four angles (0°, 45°, 90°, 315°) shown in FIGS. 12A and 12B are directions in which an etching rate of the substrate (target object) shown in FIG. 12C is measured.

Regarding the main treatment conditions when etching rates shown in FIGS. 12A and 12B are measured, the frequency of the high-frequency power supply was 13.56 MHz; the bias electric power (Bias Power) was 150 W, the flow rate of Ar gas was 250 sccm, and the process pressure was 0.4 Pa.

From the results shown in FIG. 12A, it was apparent that, in the case where the spacer is absent, the etching rates vary in the four angles, and variations in treatment on the surface of the target object occur.

From the results shown in FIG. 12B, it was apparent that, the etching rates become the same level as each other in the four angles by insertion of the spacer, and variations in treatment on the surface of the target object are solved.

From the results described above, it was observed that, by the insertion and provision of the spacer according to the embodiment, control of the aforementioned space height is carried out, and a plasma treatment contributing to a uniform profile on the substrate is achieved.

A plasma etching treatment was carried out on the substrate S serving as the target object by the object processing apparatus according to the embodiment and uniformity of an etching rate profile on the surface of the substrate S due to the spacer was evaluated.

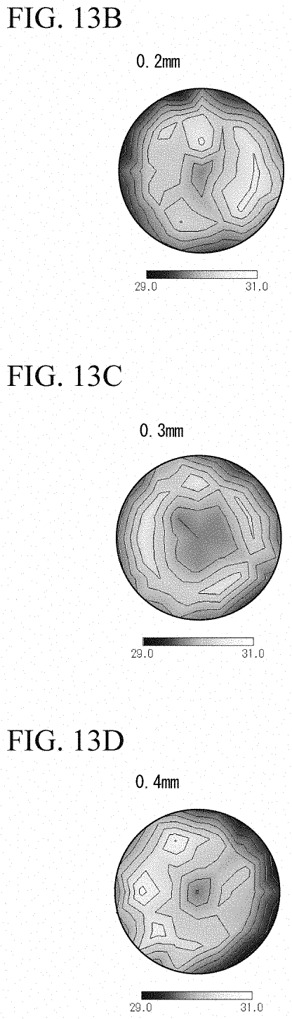

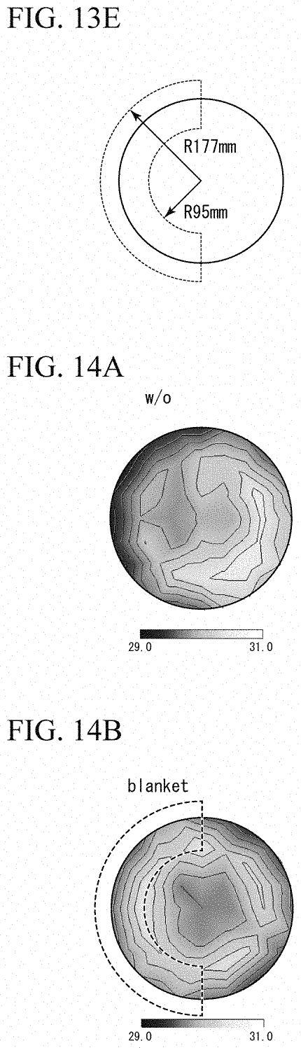

FIGS. 13A to 13E are each a map showing an etching rate and dependency of a thickness of a spacer.

FIG. 13A shows the case where the spacer is absent (w/o spacer). FIGS. 13B to 13D show the cases where the thicknesses of the spacers are 0.2 mm, 0.3 mm, and 0.4 mm in order. In FIGS. 13A to 13D, contrasting density (change in grey color) in a direction from a black region to a white region shows change in etching rate from a state where the etching rate is low to a state where the etching rate is high.

FIG. 13E is a schematic plan view showing a state where the spacer overlaps the substrate. As the spacer, the spacer that is shown in FIG. 4 and has a shape obtained by cutting off a semicircular portion that is half of the ring shape having a predetermined width in the circumferential direction, that is, “blanket shape (sheet shape)” (an internal diameter of 95 mm and an outer diameter of 177 mm).

From the results shown in FIG. 13A, in the case where the spacer is absent, it is seen that the region (white region) having a high etching rate is disproportionately distributed in the lower right of FIG. 13A.

From the results shown in FIG. 13B, in the case where the thickness of the spacer is 0.2 mm, the region (white region) having a high etching rate is distributed in the area from the right side center to the upper side center of FIG. 13B, and it is seen that the imbalanced distribution of the etching rate shown in FIG. 13A tends to disappear.

From the results shown in FIG. 13C, in the case where the thickness of the spacer is 0.3 mm, it is seen that the region (white region) having a high etching rate is distributed in a well-balanced manner in the four directions of the lower right side, the upper right side, the upper side, and the left side of FIG. 13C.

From the results shown in FIG. 13D, in the case where the thickness of the spacer is 0.4 mm, it is seen that the region (white region) having a high etching rate is disproportionately distributed in the area from the upper left side to the lower side of FIG. 13D.

From the results described above, as a result of varying the thickness of the spacer according to the embodiment, it was determined that the tendency of the etching rate profile on the surface of the substrate can be changed. In the aforementioned conditions, it was found that the most preferable result is obtained in the case where the thickness of the spacer is 0.3 mm (FIG. 13C). As stated above, it was apparent that, as a result of inserting the spacer of “blanket-shaped (sheet shape)” into the portion having a low etching rate (black region shown in FIG. 13A), the etching rate profile on the surface of the substrate can be uniform.

A plasma etching treatment was carried out on the substrate S serving as the target object by the object processing apparatus according to the embodiment and uniformity of an etching rate profile on the surface of the substrate S due to the spacer was evaluated.

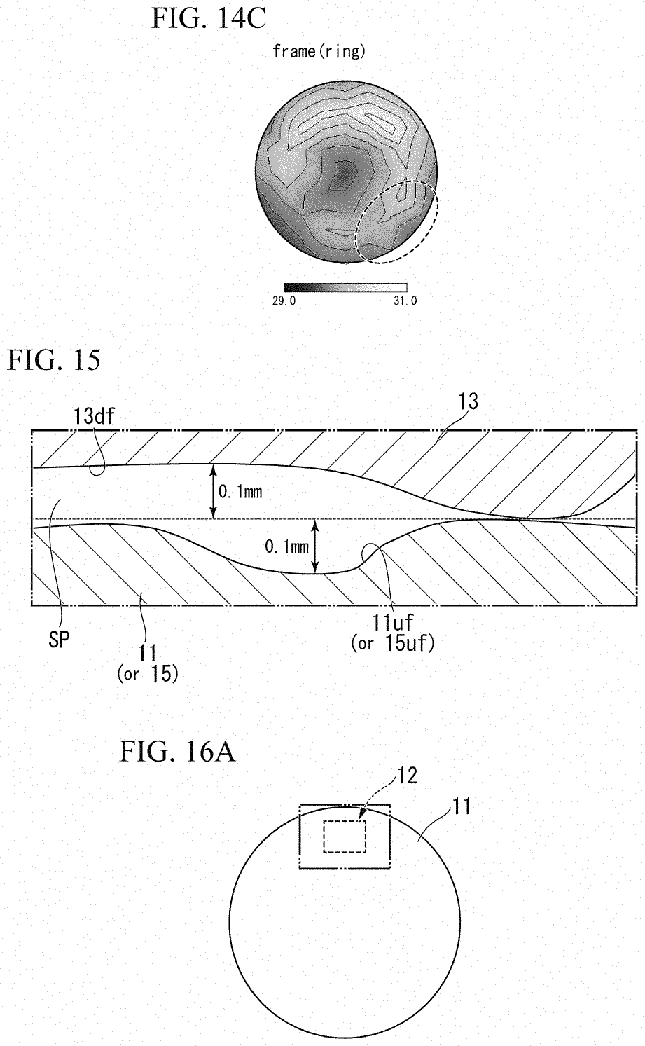

FIGS. 14A to 14C are maps each showing an etching rate and show the effects due to difference in shape of the spacer.

FIG. 14A shows the case where the spacer is absent (w/o). FIG. 14B shows the case (blanket) where the spacer is “blanket-shaped (sheet shape)”. FIG. 14C shows the case (frame (ring)) where the spacer is “frame shape (simple frame shape)”.

In FIGS. 14B and 14C, the region surrounded by a dotted line represents the region on which the spacer is disposed.

From the results shown in FIGS. 14B and 14C, as a result of varying the shape of the spacer, it was determined that the tendency of the etching rate profile on the surface of the substrate can be changed irrespective of the position into which the spacer is inserted.

FIG. 15 is a schematic cross-sectional view showing a gap due to geometric tolerance of each of two surfaces, when the two surfaces of the cover 13 and the first electrode 11 (refer to FIG. 2) facing each other are combined, or when the two surfaces of the cover 13 and the plate 15 (refer to FIG. 3) facing each other are combined. FIG. 15 shows the case where a space (gap) SP is present between a lower surface 13df of the cover 13 and an upper surface 11uf of the first electrode 11A.

The size of the space SP is determined by combination of an irregular shape on the lower surface 13df of the cover 13 (irregular state) and an irregular shape on the upper surface 11uf of the first electrode 11A. Accordingly, the size of the space SP varies depending on the position on the surfaces of the cover 13 and the upper surface 11uf of the first electrode 11A. FIG. 15 shows that the size of the space is 0.2 mm in maximum, for example, in the case where a difference in irregularity on the lower surface 13df of the cover 13 is 0.1 mm and a difference in irregularity on the upper surface 11uf of the first electrode 11A is 0.1 mm.

Consequently, the thickness of the aforementioned spacer is preferably selected in consideration of the maximum value of the sizes of the space SP. That is, as shown in the experimental results described below, it is preferable that the thickness of the spacer (thickness) be 0.1 mm to 0.5 mm and be 0.5 to 2.5 times the sum of tolerances the surfaces facing each other.

Note that, the gap that occurs between the above-mentioned two surfaces facing each other is not limited to the portion between the lower surface 13df of the cover 13 and the upper surface 11uf of the first electrode 11A. Even in the case where an upper surface 15uf of the plate 15B is adopted instead of the upper surface 11uf of the first electrode 11A, the same condition as the above is applied. That is, the lower surface 13df of the cover 13 may be replaced with the upper surface 15uf of the plate 15B.

A plasma etching treatment was carried out on the substrate S serving as the target object by the object processing apparatus according to the embodiment and uniformity of an etching rate profile on the surface of the substrate S due to the spacer was evaluated.

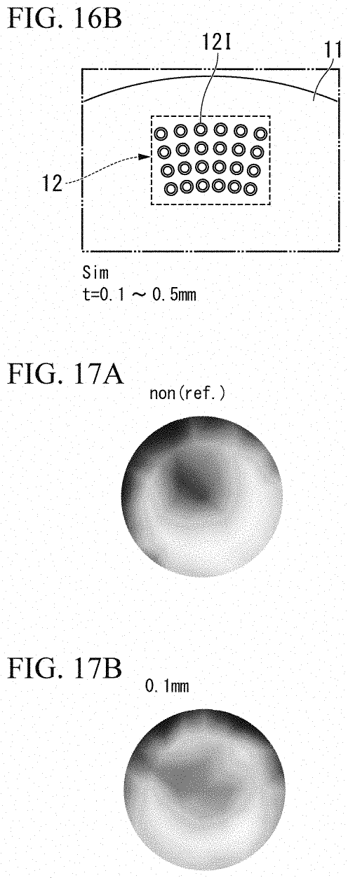

FIGS. 16A and 16B are plan views each showing a state where the pacer having “frame shape (simple frame shape)” is mounted on the plate. FIG. 16A is a plan view showing the entire plate. FIG. 16B is an enlarged plan view showing a part of the plate shown in FIG. 16A.

FIGS. 16A and 16B show the case where a plurality of spacers are arranged on the region surrounded by the dashed-dotted line shown in FIGS. 16A and 16B. The thickness t of spacer (Sim) is in the range of 0.1 to 0.5 mm.

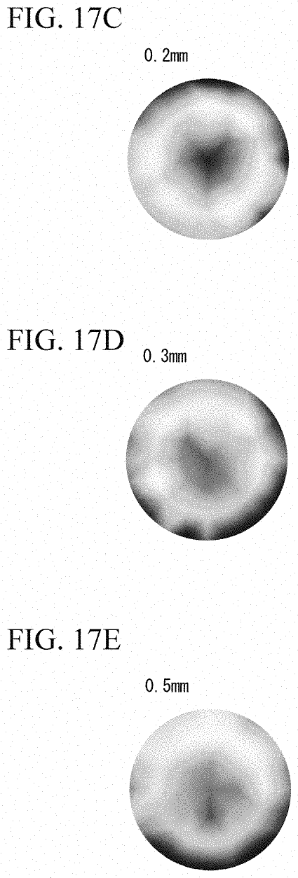

FIGS. 17A to 17E are maps showing etching rates, corresponding to FIGS. 16A and 16B, and the dependency of a thickness of a spacer. FIG. 17A shows the case where the spacer is absent, and FIGS. 17B to 17E show the cases where the thickness t of the spacer is 0.1 mm, 0.2 mm, 0.3 mm, and 0.5 mm in this order, respectively.

From the results shown in FIG. 17A, in the case where the spacer is absent, it is seen that the region (white region) having a high etching rate is disproportionately distributed in the lower side of FIG. 17A.

From the results shown in FIG. 17B, in the case where the thickness of the spacer is 0.1 mm, the region (white region) having a high etching rate is expanded in the region from the lower side to the upper side of FIG. 17B, and it is seen that the imbalanced distribution of the etching rate shown in FIG. 17A tends to disappear.

From the results shown in FIG. 17C, in the case where the thickness of the spacer is 0.2 mm, it is seen that the region (white region) having a high etching rate is formed in a ring shape and is distributed in a well-balanced manner.

From the results shown in FIG. 17D, in the case where the thickness of the spacer is 0.3 mm, it is seen that the region (white region) having a high etching rate still maintains a ring shape but is about to be transferred to the state of being slightly disproportionately distributed in the upper side of FIG. 17D.

From the results shown in FIG. 17E, in the case where the thickness of the spacer is 0.5 mm, it is seen that the region (white region) having a high etching rate is disproportionately distributed in the upper side of FIG. 17E.

From the results described above, as a result of varying the thickness of the spacer according to the embodiment, it was determined that the tendency of the etching rate profile on the surface of the substrate can be changed. In the aforementioned conditions, it was found that the most preferable result is obtained in the case where the thickness t of the spacer is 0.2 mm to 0.3 mm (FIGS. 17C and 17D). As stated above, it was apparent that, as a result of inserting the spacer of “frame shape (simple frame shape)” into the portion having a high etching rate (the white region of FIG. 17A), the profile on the surface of the substrate can be uniform.

A plasma etching treatment was carried out on the substrate S serving as the target object by the object processing apparatus according to the embodiment and uniformity of an etching rate profile on the surface of the substrate S due to the spacer was evaluated.

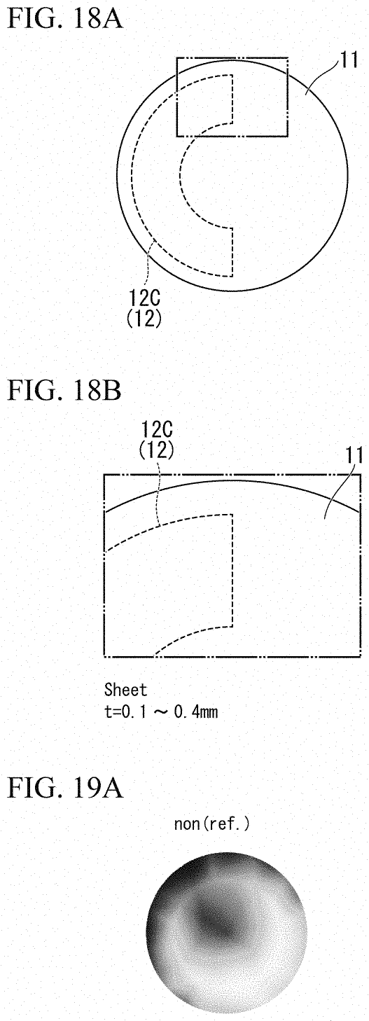

FIGS. 18A and 18B are photographs showing a state where the spacer of “blanket-shaped (sheet shape)” is mounted on the plate. FIG. 18A is a plan view showing the entire plate. FIG. 18B is an enlarged plan view showing a part of the plate.

FIGS. 18A and 18B show the case where one spacer 12C is arranged on the region surrounded by the dashed-dotted line shown in FIGS. 18A and 18B. The thickness t of the spacer 12C (Sheet) is in the range of 0.1 to 0.4 mm.

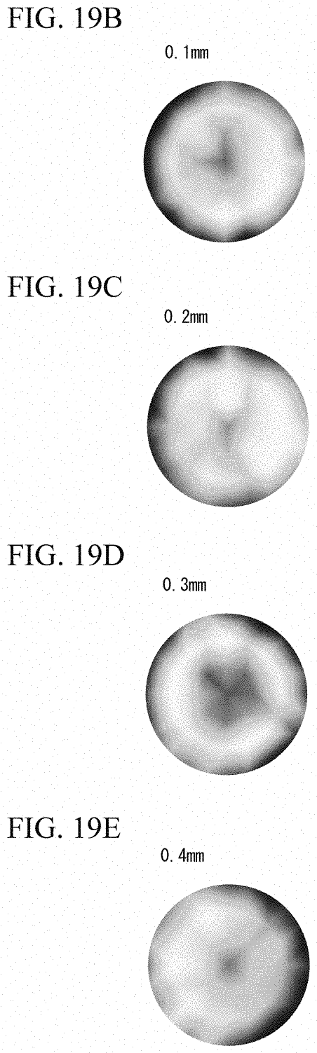

FIGS. 19A to 19E are maps showing an etching rate and corresponding to FIGS. 18A and 18B. FIGS. 19A to 19E show dependency of a thickness of a spacer. FIG. 19A shows the case where the spacer is absent, and FIGS. 19B to 19E show the cases where the thickness t of the spacer is 0.1 mm, 0.2 mm, 0.3 mm, and 0.4 mm in this order, respectively.

From the results shown in FIG. 19A, in the case where the spacer is absent, it is seen that the region (white region) having a high etching rate is disproportionately distributed in the lower side of FIG. 19A.

From the results shown in FIG. 19B, in the case where the thickness of the spacer is 0.1 mm, it is seen that the region (white region) having a high etching rate is formed in a ring shape and is distributed in a well-balanced manner.

From the results shown in FIG. 19C, in the case where the thickness of the spacer is 0.2 mm, it is seen that the region (white region) having a high etching rate maintains a ring shape, is expanded in the center of the ring shape, and is distributed in a well-balanced manner.

From the results shown in FIG. 19D, in the case where the thickness of the spacer is 0.3 mm, it is seen that, although the region (white region) having a high etching rate still maintains a ring shape, the region (black region) having a low etching rate is about to occur in the center of the ring shape.

From the results shown in FIG. 19E, in the case where the thickness of the spacer is 0.4 mm, it is seen that the region (white region) having a high etching rate is disproportionately distributed in the right side of FIG. 19E.

From the results described above, according to the embodiment, as a result of varying the thickness of the spacer, it was determined that the tendency of the etching rate profile on the surface of the substrate can be changed. In the aforementioned conditions, it was found that the most preferable result is obtained in the case where the thickness of the spacer is 0.2 mm (FIG. 19C). As stated above, it was apparent that, as a result of inserting the spacer of “blanket-shaped (sheet shape)” into the portion having a low etching rate (black region shown in FIG. 19A), the profile on the surface of the substrate can be uniform.

A plasma etching treatment was carried out on the substrate S serving as the target object by the object processing apparatus according to the embodiment and uniformity of an etching rate profile on the surface of the substrate S due to the spacer was evaluated.

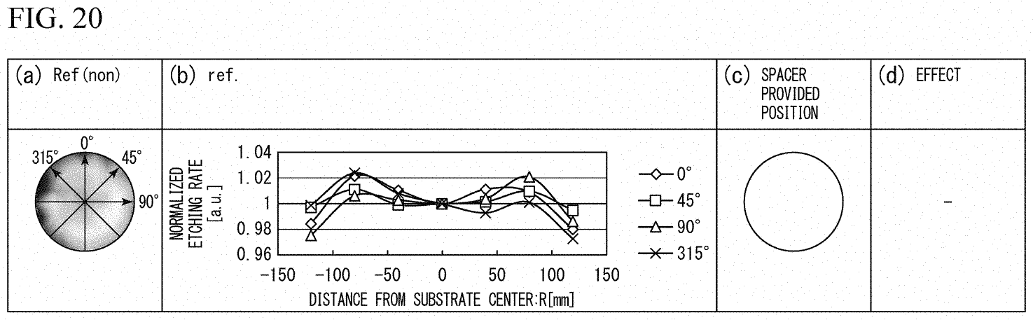

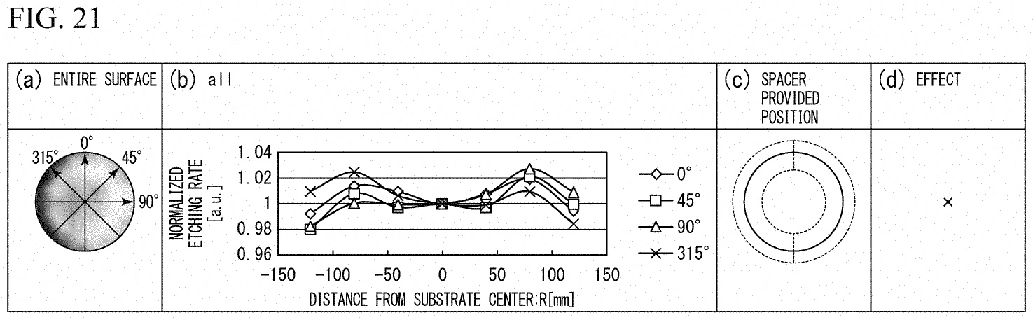

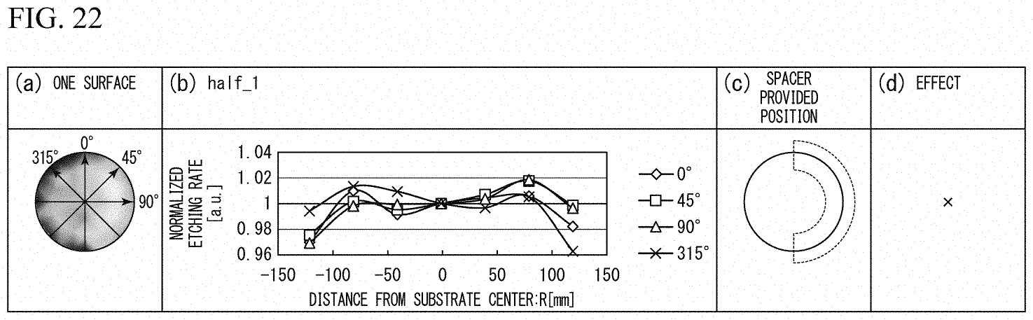

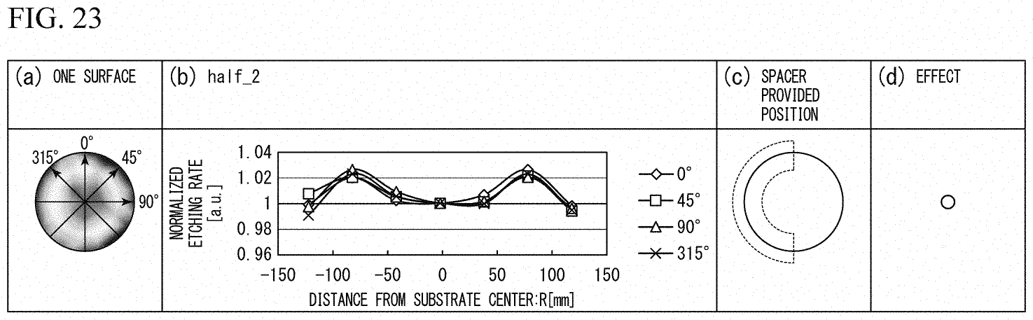

FIGS. 20 to 23 show the results of evaluation by varying the position at which the spacer is provided. FIG. 20 shows an experimental example 1 (the case where the spacer is absent), FIG. 21 shows an experimental example 2 (the case where the spacer is provided at the entire periphery), FIG. 22 shows an experimental example 3 (the case where the spacer is provided at the right semicircular portion), and FIG. 23 shows an experimental example 4 (the case where the spacer is provided at the left semicircular portion).

### Experimental Example 1

FIG. 20 is a list showing the evaluation result of an experimental example 1 (the case where the spacer is absent). Part (a) of FIG. 20 shows a map showing an etching rate. Part (b) of FIG. 20 shows a graph showing a normalized etching rate. Part (c) of FIG. 20 shows the position into which the spacer is inserted. Part (d) of FIG. 20 shows the effect. The four angles (0°, 45°, 90°, 315°) shown in Part (b) of FIG. 20 are directions in which an etching rate of the substrate (target object) shown in FIG. 20 Part (a) is measured.

In the case of the experimental example 1, as apparent from Part (b) of FIG. 20, the normalized etching rates are significantly different from each other in four angles. That is, in the experimental example 1, it is seen that, the etching rate with respect to the target object is highly dependent on the angle, and the etching rate profile on the surface of the substrate (target object) is non-uniform.

### Experimental Example 2

FIG. 21 is a list showing the evaluation result of an experimental example 2 (the case where the spacer is provided at the entire periphery). Part (a) of FIG. 21 shows a map showing an etching rate. Part (b) of FIG. 21 shows a graph showing a normalized etching rate. Part (c) of FIG. 21 shows the position into which the spacer is inserted. Part (d) of FIG. 21 shows the effect. The four angles (0°, 45°, 90°, 315°) shown in Part (b) of FIG. 21 are directions in which an etching rate of the substrate (target object) shown in FIG. 21 Part (a) is measured.

In the case of the experimental example 2, as apparent from Part (b) of FIG. 21, the normalized etching rates are significantly different from each other in four angles. That is, it is seen that, the etching rate with respect to the target object is highly dependent on the angle, and the etching rate profile on the surface of the substrate (target object) is non-uniform. In the experimental example 2, even where the spacer shown in Part (c) of FIG. 21 is provided the entire periphery, it was determined that, similar to the experimental example 1, the angle dependency of the etching rate is not changed.

### Experimental Example 3

FIG. 22 is a list showing the evaluation result of an experimental example 3 (the case where the spacer is provided at the right semicircular portion). Part (a) of FIG. 22 shows a map showing an etching rate. Part (b) of FIG. 22 shows a graph showing a normalized etching rate. Part (c) of FIG. 22 shows the position into which the spacer is inserted. Part (d) of FIG. 22 shows the effect.

In the case of the experimental example 3, as apparent from Part (b) of FIG. 22, the normalized etching rates are different from each other in four angles. That is, in experimental example 3, it is seen that, although the angle dependency of the etching rate with respect to the target object is reduced as compared with the experimental example 1 or the experimental example 2, the etching rate profile on the surface of the substrate is still non-uniform. Even where the spacer is provided on at the right semicircular portion of Part (c) of FIG. 22 as shown in the experimental example 3, it was determined that, similar to the experimental example 1, the angle dependency of the etching rate remains.

### Experimental Example 4

FIG. 23 is a list showing the evaluation result of an experimental example 4 (the case where the spacer is provided at the left semicircular portion). Part (a) of FIG. 23 shows a map showing an etching rate. Part (b) of FIG. 23 shows a graph showing a normalized etching rate. Part (c) of FIG. 23 shows the position into which the spacer is inserted. Part (d) of FIG. 23 shows the effect.

In the case of the experimental example 4, as apparent from Part (b) of FIG. 23, the normalized etching rates have almost the same tendency in the four angles. That is, in the experimental example 4, it is seen that, the etching rate with respect to the target object the angle dependency almost disappears as compared with the experimental example 1 or the experimental example 2, and the etching rate profile on the surface of the substrate can be uniform. As a result of disposing the spacer at the left semicircular portion shown in Part (c) of FIG. 23 as shown in the experimental example 4, it was determined that the angle dependency of the etching rate of the experimental example 1 is eliminated.

From the results shown in FIGS. 20 to 23, it was determined that, as a result of varying the position at which the spacer is provided in the embodiment, the tendency of the etching rate profile on the surface of the substrate can be changed. In the aforementioned condition, it was determined that, the experimental example 4 (the case where the spacer is provided at the left semicircular portion as shown in Part (b) of FIG. 23) can obtain the best results. As stated above, it was apparent that, as a result of inserting the spacer of “blanket-shaped (sheet shape)” into the portion having a low etching rate (black region shown in Part (a) of FIG. 20), the etching rate profile on the surface of the substrate can be uniform.

As described above, the object processing apparatus according to the embodiment was explained, the invention is not limited to the embodiments, and various modifications may be made insofar as they do not depart from the scope of the invention.

### INDUSTRIAL APPLICABILITY

The invention is widely applicable to an object processing apparatus. For example, the object processing apparatus of the invention is preferably used in the case where a target object has a large area, the case where it is necessary to adjust conditions (process pressure, processing gas) of etching treatment with respect to a target object, or the like.

### DESCRIPTION OF REFERENCE NUMERALS

AT second electrode (antenna coil), D isolation valve, G gas introduction device, P pumping device, S target object (substrate), 10 (10A, 10B) mounting unit, 11 (11A, 11B) first electrode (support base), 12 plate (adjustment plate), 12A to 12J spacer, 13 (13A, 13B) cover (electrode cover), 16a first matching box (M/B), 16b first power supply, 17 chamber, 18a second matching box (M/B), 18b second power supply.

What is claimed is:

1. An object processing apparatus, comprising:
a chamber that has an internal space able to be depressurized and is configured such that a target object is subjected to a plasma treatment in the internal space;
a first electrode that is disposed in the chamber and on which the target object is to be mounted;
a first power supply that applies a bias voltage of negative potential to the first electrode;
a gas introduction device that introduces a processing gas into an inside of the chamber; and
a pumping device that depressurizes the inside of the chamber, wherein
a cover is provided between the first electrode and the target object so as to cover the first electrode, and
a spacer is located between the first electrode and the cover, and is disposed so as to occupy a localized region.

2. The object processing apparatus according to claim 1, wherein the spacer is formed of a thin structure.

3. The object processing apparatus according to claim 2, wherein a thickness (mm) of the spacer is 0.1 to 0.5.

4. The object processing apparatus according to claim 2, wherein a thickness (mm) of the spacer is 0.5 to 2.5 times the sum of tolerances of the first electrode and the cover on a surface on which the first electrode and the cover face each other.

5. The object processing apparatus according to claim 1, wherein the spacer is formed of a hollow structure.

6. The object processing apparatus according to claim 5, wherein a thickness (mm) of the spacer is 0.1 to 0.5.

7. The object processing apparatus according to claim 5, wherein a thickness (mm) of the spacer is 0.5 to 2.5 times the sum of tolerances of the first electrode and the cover on a surface on which the first electrode and the cover face each other.

8. The object processing apparatus according to claim 1, further comprising a conductive plate provided between the first electrode and the cover, wherein
the spacer is disposed between the cover and the plate.
